(19) United States
(12) Patent Application Publication
(10) Pub. No.: US 2024/0234495 A1
(43) Pub. Date: Jul. 11, 2024

(54) GATE TRENCH POWER SEMICONDUCTOR DEVICES HAVING SELF-ALIGNED TRENCH SHIELDING REGIONS AND RELATED METHODS

(71) Applicant: Wolfspeed, Inc., Durham, NC (US)

(72) Inventors: Woongsun Kim, Cary, NC (US); Naeem Islam, Morrisville, NC (US); Madankumar Sampath, Durham, NC (US); Sei-Hyung Ryu, Cary, NC (US); Rahul R. Potera, Raleigh, NC (US); In-Hwan Ji, Cary, NC (US)

(21) Appl. No.: 18/093,343

(22) Filed: Jan. 5, 2023

(51) Int. Cl. H01L 29/06; H01L 21/04; H01L 29/16; H01L 29/66; H01L 29/78

(52) U.S. Cl. CPC H01L 29/063; H01L 21/0465; H01L 21/049; H01L 29/1608; H01L 29/66068; H01L 29/7813

(57) ABSTRACT

A method of forming a semiconductor device comprises forming a first mask that includes a longitudinally-extending first opening that has a first width on a semiconductor layer structure. A spacer is formed on sidewalls of the first mask that are exposed by the first opening to form a second mask, where the first and second masks comprise a mask structure that has a longitudinally-extending second opening that has a second width that is smaller than the first width. Dopants are implanted through the second opening to form an implanted region in the semiconductor layer structure. The spacer is at least partially removed from the sidewalls of the first mask to form a third opening in the mask structure. The semiconductor layer structure is then etched using the mask structure as an etch mask to form a gate trench in the semiconductor layer structure underneath the third opening.

### FIELD OF THE INVENTION

The present invention relates to power semiconductor devices and, more particularly, to power semiconductor devices having gate trenches and to methods of fabricating such devices.

### BACKGROUND

A Metal Insulating Semiconductor Field Effect Transistor (“MISFET”) is a well-known type of semiconductor transistor that may be used as a switching device. A MISFET is a three terminal device that has gate, drain and source terminals and a semiconductor body. The semiconductor body is referred to herein as a “semiconductor layer structure.” A source region and a drain region are formed in the semiconductor layer structure that are separated by a channel region, and a gate electrode (which may act as the gate terminal or be electrically connected to the gate terminal) is disposed adjacent the channel region and separated from the channel region by a thin insulating layer. A MISFET may be turned on or off by setting a bias voltage that is applied to the gate electrode to be above or below a threshold value. When a MISFET is turned on (i.e., it is in its “on-state”), current is conducted through the channel region of the MISFET between the source and drain regions. When the bias voltage is reduced below the threshold level, the current ceases to conduct through the channel region.

An n-type MISFET has source and drain regions that have n-type (electron) conductivity and a channel that has p-type (hole) conductivity. An n-type MISFET thus has an “n-p-n” design. An n-type MISFET turns on when a gate bias voltage is applied to the gate electrode that is sufficient to create a conductive n-type inversion layer in the p-type channel region that electrically connects the n-type source and drain regions, thereby allowing for majority carrier conduction therebetween. A P-type MISFET has a “p-n-p” design and turns on when a gate bias voltage is applied to the gate electrode that is sufficient to create a conductive p-type inversion layer in the n-type channel region that electrically connects p-type source and drain regions. Herein, the terms “first conductivity type” and “second conductivity type” are used to indicate either n-type or p-type, where the first and second conductivity types are different. Thus, if a first region of a device has a first conductivity type and a second region of the device has a second conductivity type, this means either that the first region has n-type conductivity and the second region has p-type conductivity or, alternatively, that first region has p-type conductivity and the second region has n-type conductivity.

As noted above, the gate electrode of a MISFET is separated from the channel region by a thin dielectric layer that is called a gate dielectric layer. Typically, power MISFETs implement the thin gate dielectric layer using an oxide layer such as a silicon oxide layer. A MISFET that includes an oxide gate dielectric layer is referred to as a Metal Oxide Semiconductor Field Effect Transistor (“MOSFET”), and the gate dielectric layer is referred to as a gate oxide layer. As oxide gate dielectric layers are almost always used implemented as gate oxide layers due to their superior properties in most applications, the discussion herein will focus on MOSFETs as opposed to MISFETs. It will be appreciated, however, that the techniques according to embodiments of the present invention that are described herein are equally applicable to devices having gate dielectric layers formed with materials other than oxides.

Because the gate electrode of a MOSFET is insulated from the channel region by the gate oxide layer, minimal gate current is required to maintain the MOSFET in its on-state or to switch a MOSFET between its on-state and its off-state. The gate current is kept small during switching because the gate forms a capacitor with the channel region. Thus, only minimal charging and discharging current is required during switching, allowing for less complex gate drive circuitry and faster switching speeds. MOSFETs may be stand-alone devices or may be combined with other circuit devices. For example, an Insulated Gate Bipolar Transistor (“IGBT”) is a semiconductor device that includes both a MOSFET and a Bipolar Junction Transistor (“BJT”) that combines the high impedance gate electrode of the MOSFET with the small on-state conduction losses that may be provided by a BJT. An IGBT may be implemented, for example, as a Darlington pair that includes a high voltage n-channel MOSFET at the input and a BJT at the output. The base current of the BJT is supplied through the channel of the MOSFET, thereby allowing a simplified external drive circuit (since the drive circuit only charges and discharges the gate electrode of the MOSFET).

In some applications, MOSFETs may need to carry large currents and/or be capable of blocking high voltages. Such MOSFETs are often referred to as “power” MOSFETs. Power MOSFETs are often fabricated from wide band-gap semiconductor materials (herein, the term “wide band-gap semiconductor” encompasses any semiconductor having a band-gap of at least 1.4 eV). Power semiconductor devices are often formed in silicon carbide (“SiC”), which has a number of advantageous characteristics including, for example, a high electric field breakdown strength, high thermal conductivity, high electron mobility, high melting point and high-saturated electron drift velocity.

Power semiconductor devices such as power MOSFETs can have a lateral structure or a vertical structure. In a device having a lateral structure, the terminals of the device (e.g., the drain, gate and source terminals for a power MOSFET) are on the same major surface (i.e., top or bottom) of a semiconductor layer structure. In contrast, in a device having a vertical structure, at least one terminal is provided on each major surface of the semiconductor layer structure (e.g., in a vertical MOSFET, the source and gate may be on the top surface of the semiconductor layer structure and the drain may be on the bottom surface of the semiconductor layer structure). The semiconductor layer structure may or may not include an underlying substrate such as a growth substrate. Herein, the term “semiconductor layer structure” refers to a structure that includes one or more semiconductor layers, such as semiconductor substrates and/or semiconductor epitaxial layers.

The semiconductor layer structure of a power semiconductor device typically includes an “active region” in which one or more functional semiconductor devices are formed. The active region acts as a main junction for blocking voltage during reverse bias (off-state) operation and providing current flow during forward bias (on-state) operation. The power semiconductor device may also have an edge termination in a termination region of the semiconductor layer structure that is adjacent (and typically surrounding) the active region. Typically, multiple power semiconductor devices are formed in/on a common wafer, and each power semiconductor device will typically have its own edge termination. After the wafer is fully processed, the resultant structure may be diced to separate the individual edge-terminated power semiconductor devices. Each power semiconductor device may have a unit cell structure in which the active region of each power semiconductor device includes a plurality of individual “unit cell” devices that are electrically connected in parallel and that together function as a single power semiconductor device.

Vertical power semiconductor devices that include a MOSFET can have a standard gate electrode design in which the gate electrode of the transistor is formed on top of the semiconductor layer structure or, alternatively, may have the gate electrode buried in a gate trench within the semiconductor layer structure. MOSFETs having buried gate electrodes are typically referred to as gate trench MOSFETs. With the standard gate electrode design, the channel region of each unit cell transistor is horizontally disposed underneath the gate electrode. In contrast, in the gate trench MOSFET design, the channels are typically vertically disposed. Gate trench MOSFETs may provide enhanced performance, but typically require a more complicated manufacturing process.

One failure mechanism for a power MOSFET is the so-called “breakdown” of the gate oxide layer. The gate oxide layer is subjected to high electric fields during normal device operation. The stress on the gate oxide layer caused by these electric fields generates defects in the oxide material that build up over time. When the concentration of defects reaches a critical value, a so-called “percolation path” may be created through the gate oxide layer that electrically connects the gate electrode to the source or drain region, thereby creating a short-circuit that can destroy the device. The “lifetime” of a gate oxide layer (i.e., how long the device can be operated before breakdown occurs) is a function of, among other things, the magnitude of the electric field that the gate oxide layer is subjected to and the length of time for which the electric field is applied. FIG. 1 is a schematic graph illustrating the relationship between the operating time until breakdown occurs (the “gate oxide lifetime”) and the level of the electric field applied to the gate oxide layer. This graph assumes that the same electric field is always applied (which is not necessarily the case), and assumes a gate oxide layer having a certain thickness. As shown in FIG. 1, the relationship may, in some cases, be generally linear when the gate oxide lifetime is plotted on a logarithmic scale. The important point to take from FIG. 1 is that as the electric field level is increased, the lifetime of the gate oxide layer decreases exponentially. The lifetime of the gate oxide layer may be increased by increasing the thickness of the gate oxide layer, but various performance parameters of a MOSFET may be a function of the thickness of the gate oxide layer and thus increasing the thickness of the gate oxide layer is typically not an acceptable way of increasing the lifetime of the gate oxide layer.

### SUMMARY

Pursuant to some embodiments of the present invention, semiconductor devices are provided that comprise a wide band-gap semiconductor layer structure. The wide band-gap semiconductor layer structure comprises a drift region having a first conductivity type, a well region having a second conductivity type on the drift region, a source region having the first conductivity type on the well region, a gate electrode within a gate trench, and a trench shielding region having the second conductivity type underneath the gate trench. A width of the trench shielding region exceeds a width of the gate trench.

In some embodiments, the trench shielding region is formed underneath the gate trench and extends onto lower portions of opposed sidewalls of the gate trench.

In some embodiments, the gate trench has left and right sidewalls that extend in parallel to a longitudinal axis of the gate trench, the left and right sidewalls spaced apart from each other in a lateral direction, and wherein a left side of the trench shielding region extends laterally beyond the lower edge of the left sidewall of the gate trench by at least 0.1 microns, and the right side of the trench shielding region extends laterally beyond the lower edge of the right sidewall of the gate trench by at least 0.1 microns.

In some embodiments, the gate trench has left and right sidewalls that extend in parallel to a longitudinal axis of the gate trench, the left and right sidewalls spaced apart from each other in a lateral direction, and wherein the gate trench overlaps less than 95% of a lateral width of the trench shielding region.

In some embodiments, lower corners of the gate trench are rounded corners.

In some embodiments, the drift region, the well region, the source region and the shielding region each comprise silicon carbide.

In some embodiments, the trench shielding region extends continuously across the full width of the gate trench.

In some embodiments, the trench shielding region defines the bottom of the gate trench.

In some embodiments, the gate trench has left and right sidewalls that extend in parallel to a longitudinal axis of the gate trench, the left and right sidewalls spaced apart from each other in a lateral direction, and wherein a left side of the trench shielding region extends laterally beyond the lower edge of the left sidewall of the gate trench by at least 0.3 microns, and the right side of the trench shielding region extends laterally beyond the lower edge of the right sidewall of the gate trench by at least 0.3 microns.

Pursuant to further embodiments of the present invention, semiconductor devices are provided that comprise a wide band-gap semiconductor layer structure that comprises a drift region having a first conductivity type, a well region having a second conductivity type on the drift region, a source region having the first conductivity type on the well region, a gate electrode within a gate trench, and a trench shielding region having the second conductivity type underneath the gate trench. A portion of the drift region having the first conductivity type is interposed between a bottom surface of the gate trench and the trench shielding region.

In some embodiments, the gate trench has left and right sidewalls that extend in parallel to a longitudinal axis of the gate trench, the left and right sidewalls spaced apart from each other in a lateral direction, and wherein a left side of the trench shielding region extends laterally beyond the lower edge of the left sidewall of the gate trench by at least 0.1 microns, and the right side of the trench shielding region extends laterally beyond the lower edge of the right sidewall of the gate trench by at least 0.1 microns.

In some embodiments, the gate trench has left and right sidewalls that extend in parallel to a longitudinal axis of the gate trench, the left and right sidewalls spaced apart from each other in a lateral direction, and wherein the gate trench overlaps less than 95% of a lateral width of the trench shielding region.

In some embodiments, lower corners of the gate trench are rounded corners.

In some embodiments, the trench shielding region extends continuously across the full width of the gate trench.

In some embodiments, the gate trench has left and right sidewalls that extend in parallel to a longitudinal axis of the gate trench, the left and right sidewalls spaced apart from each other in a lateral direction, and wherein a left side of the trench shielding region extends laterally beyond the lower edge of the left sidewall of the gate trench by at least 0.3 microns, and the right side of the trench shielding region extends laterally beyond the lower edge of the right sidewall of the gate trench by at least 0.3 microns.

Pursuant to further embodiments of the present invention, methods of forming a semiconductor device are provided. Pursuant to these methods, a first mask is formed on a semiconductor layer structure, the first mask including a longitudinally-extending first opening that has a first width. A spacer is formed on sidewalls of the first mask that are exposed by the first opening to form a second mask, the first and second masks comprising a mask structure that has a longitudinally-extending second opening that has a second width that is smaller than the first width. Dopants are implanted into the semiconductor layer structure through the second opening to form an implanted region in the semiconductor layer structure. The spacer is at least partially removed from the sidewalls of the first mask to form a third opening in the mask structure. Finally, the semiconductor layer structure is etched using the mask structure as an etch mask to form a gate trench in the semiconductor layer structure underneath the third opening.

In some embodiments, the second mask comprises silicon. In some embodiments, the second mask further comprises oxygen. In some embodiments, the first mask comprises both silicon and nitrogen.

In some embodiments, forming the spacer on sidewalls of the first mask that are exposed by the first opening to form the second mask comprises oxidizing the sidewalls of the first mask that are exposed by the first opening.

In some embodiments, the implanted region is underneath the gate trench and a width of the implanted region is larger than a width of the gate trench.

In some embodiments, the implanted region extends onto lower portions of opposed sidewalls of the gate trench.

In some embodiments, lower corners of the gate trench are rounded corners.

In some embodiments, the drift region, the well region, the source region and the shielding region each comprise silicon carbide.

In some embodiments, drift region having a first conductivity type, a well regions having a second conductivity type, and a source region having the first conductivity type, wherein at least a portion of the well region is positioned in between the drift region and the source region, and the implanted region has the second conductivity type.

In some embodiments, the implanted region is self-aligned with the gate trench.

In some embodiments, the method further comprises removing some but not all of a portion of the second mask that is within the second opening prior to implanting the dopants into the semiconductor layer structure.

In some embodiments, etching the semiconductor layer structure using the mask structure as an etch mask to form a gate trench in the semiconductor layer structure underneath the third opening exposes the implanted region.

In some embodiments, the method further comprises, after etching the semiconductor layer structure using the mask structure as an etch mask to form a gate trench in the semiconductor layer structure underneath the third opening, performing an oxidation treatment on the semiconductor layer structure and then removing oxidized portions of the semiconductor layer structure.

In some embodiments, the method further comprises, after etching the semiconductor layer structure using the mask structure as an etch mask to form a gate trench in the semiconductor layer structure underneath the third opening, annealing the semiconductor layer structure in a hydrogen containing environment.

In some embodiments, at least partially removing the spacer from the sidewalls of the first mask to form the third opening in the mask structure comprises completely removing the spacer from the sidewalls of the first mask so that the third opening has the first width.

Pursuant to still further embodiments of the present invention, methods of forming a semiconductor device are provided in which a first mask is formed on a semiconductor layer structure, the first mask including a first opening. A spacer is formed on sidewalls of the first mask that are exposed by the first opening to form a second mask, the first and second masks comprising a mask structure that has a second opening. Dopants are implanted into the semiconductor layer structure through the second opening to form an implanted region in the semiconductor layer structure. The spacer is at least partially removed from the sidewalls of the first mask. The semiconductor layer structure is the etched to form a gate trench that is self-aligned with the implanted region.

In some embodiments, the semiconductor layer structure is a wide band-gap semiconductor layer structure that comprises a drift region having a first conductivity type, a well layer having a second conductivity type, and a source region having the first conductivity type on the well layer, wherein the dopants that are implanted into the semiconductor layer structure through the second opening are second conductivity type dopants.

In some embodiments, at least partially removing the spacer from the sidewalls of the first mask comprises completely removing the spacer from the sidewalls of the first mask so that the semiconductor layer structure is etched solely using the first mask as an etch mask.

In some embodiments, the implanted region is a trench shielding region that has the second conductivity type.

In some embodiments, the second opening exposes the semiconductor layer structure.

In some embodiments, the spacer covers the semiconductor layer structure exposed by the first opening so that the second opening does not expose the semiconductor layer structure.

In some embodiments, the method further comprises, after, etching the semiconductor layer structure to form the gate trench, then removing the first mask, then oxidizing exposed portions of the semiconductor layer structure, and then removing the oxidized portions of the semiconductor layer structure.

In some embodiments, the method further comprises, after etching the semiconductor layer structure to form the gate trench, the bottom corners of the gate trench may be rounded, and/or the implanted second conductivity dopants may be activated via a heating step.

In some embodiments, the second mask comprises silicon. In some embodiments, the second mask further comprises oxygen. In some embodiments, the first mask comprises both silicon and nitrogen.

In some embodiments, forming the spacer on sidewalls of the first mask that are exposed by the first opening to form the second mask comprises oxidizing the sidewalls of the first mask.

In some embodiments, the implanted region is underneath the gate trench and a width of the implanted region is larger than a width of the gate trench.

In some embodiments, the implanted region extends onto lower portions of opposed sidewalls of the gate trench.

Pursuant to additional embodiments of the present invention, methods of forming a semiconductor device are provided. Pursuant to these methods, a semiconductor layer structure is provided that comprises a drift region having a first conductivity type, a well region having a second conductivity type on the drift region, and a source region having the first conductivity type on the well region. A first mask is formed on the semiconductor layer structure, the first mask including a first opening. Second conductivity type dopants are implanted into the semiconductor layer structure through at least a portion of the semiconductor layer structure that was exposed by the first opening to form an implanted region that has the second conductivity type in the drift region. After the second conductivity type dopants are implanted into the semiconductor layer structure a portion of the source region that is exposed through the first opening still has the first conductivity type.

In some embodiments, after the second conductivity type dopants are implanted into the semiconductor layer structure a portion of the drift region that is in between the well region and the implanted region still has the first conductivity type.

In some embodiments, the first opening is a longitudinally-extending first opening that has a first width, the method further comprising forming a spacer on sidewalls of the first mask that are exposed by the first opening to form a second mask, the first and second masks comprising a mask structure that has a longitudinally-extending second opening that has a second width that is smaller than the first width. In such embodiments, the second conductivity type dopants may be implanted into the semiconductor layer structure through the second opening.

In some embodiments, the method further comprises, at least partially removing the spacer from the sidewalls of the first mask to form a third opening in the mask structure and then etching the semiconductor layer structure using the mask structure as an etch mask to form a gate trench in the semiconductor layer structure underneath the third opening.

In some embodiments, the first mask comprises a material that includes both silicon and nitrogen and the second mask comprises silicon.

In some embodiments, the second mask further comprises oxygen.

In some embodiments, the implanted region is underneath the gate trench and a width of the implanted region is larger than a width of the gate trench.

In some embodiments, the implanted region extends onto lower portions of opposed sidewalls of the gate trench.

### BRIEF DESCRIPTION OF THE DRAWINGS

FIG. 1 is a schematic graph illustrating the relationship between the operating time until breakdown and the electric field level applied to the gate oxide layer of a power semiconductor device.

FIGS. 2A-2L are schematic vertical cross-sectional views and FIG. 2M is a schematic horizontal cross-sectional view that illustrate a method of fabricating a gate trench power MOSFET according to embodiments of the present invention.

FIGS. 2N and 20 are schematic horizontal cross-sectional views illustrating different possible connection schemes between the p-well and the source contact that could be used in place of the connection scheme shown in FIG. 2M.

FIGS. 3A and 3B are schematic vertical cross-sectional views that correspond to FIG. 2H that illustrate modified versions of the gate trench power MOSFET of FIGS. 2A-2M.

FIG. 4 is a schematic vertical cross-sectional view that corresponds to FIG. 2D that illustrates another method of fabricating the gate trench power MOSFET of FIGS. 2L-2M.

FIGS. 5A-5E are schematic vertical cross-sectional views and FIG. 5F is a schematic horizontal cross-sectional view that illustrate a method of fabricating a gate trench power MOSFET according to further embodiments of the present invention.

FIG. 6 is a schematic vertical cross-sectional view that corresponds to FIG. 5C that illustrates a modified version of the gate trench power MOSFET of FIGS. 5A-5F.

FIGS. 7-8 are flow charts illustrating methods of fabricating a gate trench semiconductor devices according to embodiments of the present invention.

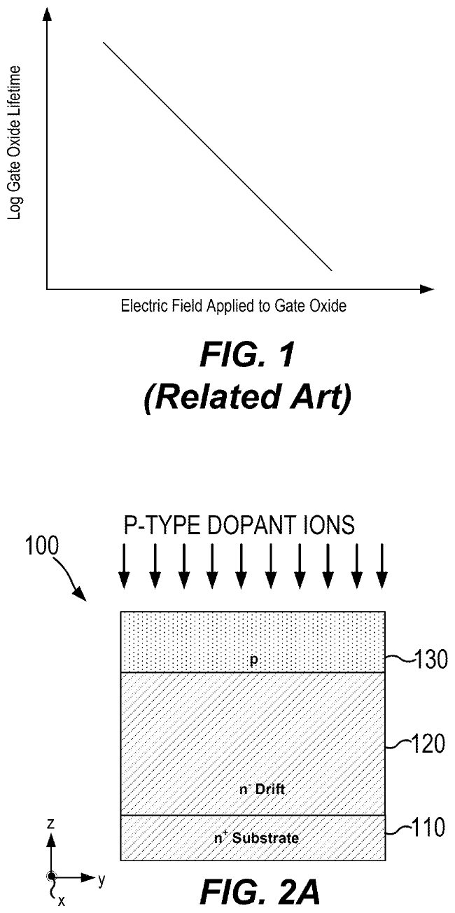

### DETAILED DESCRIPTION

Vertical silicon carbide based power semiconductor devices that have gate trenches such as vertical power MOSFETs and IGBTs are attractive for many applications due to their inherent lower specific on-resistance, which may result in more efficient operation for power switching operations. Gate trench vertical power devices exhibit lower specific resistance during on-state operation because the channel is formed in the sidewall of the gate trench. Moreover, the carrier mobility in sidewall channels may be about 2-4 times higher than the corresponding carrier mobility in the horizontal channel of a standard (i.e., non-gate trench) vertical power device, which results in increased current density during on-state operation allowing for higher switching speeds. Furthermore, the gate trench design reduces the overall pitch of the device, allowing for increased integration. The lower conduction losses (due to the reduced on-state resistance) and improved switching speeds make gate trench power devices well-suited for high frequency power applications having low to moderate voltage blocking requirements (e.g., 600-1200 Volts). These devices may have reduced requirements for associated passive components and require relatively simple cooling schemes. As MOSFETs are the most widely used silicon carbide based trenched power semiconductor gate devices, the discussion below focuses on MOSFET embodiments. It will be appreciated, however, that each of the described embodiments may alternatively be implemented using non-oxide gate dielectric layers (e.g., nitrides, high dielectric constant materials, etc.), and that the same techniques may be used to form other gate trench power semiconductor devices such as IGBTs, gate-controlled thyristors and the like.

As discussed above, gate trench power MOSFETs are susceptible to oxide reliability issues due to the presence of high electric fields in the gate oxide layers that line the bottoms and sidewalls of the gate trenches. The high electric fields degrade the gate oxide layer over time, and may eventually result in failure of the device. When gate trench MOSFETs operate in reverse blocking operation (i.e., when the MOSFET is in its off-state), the source terminal of the MOSFET is typically grounded, the gate terminal is typically grounded or at a negative bias voltage, and the drain terminal is typically at a high positive voltage. Under such reverse blocking operations, high electric fields extend upwardly from the drain terminal (which is on the bottom surface of the semiconductor layer structure) toward the top surface of the semiconductor layer structure. Thus, under reverse blocking operation, the bottom portion of the gate dielectric layer experiences the highest electric field levels. Due to electric field crowding effects, the electric field levels at the lower “corners” of the gate oxide layer at the bottom edges of the gate trench may be particularly high (i.e., the portions of the gate oxide layers that cover the region where the sidewalls of the gate trenches merge into the bottom of the gate trenches). Moreover, due to the difference in permittivity between silicon carbide and silicon oxide, the electric field in the silicon oxide gate oxide layer may be about 2.6 times higher than the electric field in the adjacent silicon carbide. Breakdown of the silicon oxide occurs when the electric field reaches a critical level Ecr. In order to avoid such breakdown, power MOSFETs may be operated with the drain voltage at lower levels during reverse blocking operation to ensure that the electrical field does not reach a level that will result in breakdown. In other words, the voltage rating of a power MOSFET may be set to ensure that premature gate oxide breakdown will not occur.

So-called “trench shielding regions” are often provided underneath the gate trenches of conventional gate trench power MOSFETs in order to reduce the electric field levels in the gate oxide layer during reverse blocking operation. These trench shielding regions comprise highly doped semiconductor layers having the same conductivity type as the channel region of the device. The discussion below focuses on n-type devices that have p-type channel and trench shielding regions. The trench shielding regions may, for example, extend downwardly 0.5 to 1.0 microns or more from the bottoms of the gate trenches into the semiconductor layer structure of the device. The protection that these trench shielding regions provide to the gate oxide layer increases with increasing depth of the trench shielding region. The trench shielding regions are electrically connected to the source terminal of the MOSFET by p-type trench shielding region connection patterns. These trench shielding connection patterns may be in and/or outside the active region of the device.

The trench shielding regions are typically formed via one or more ion implantation processes in which p-type dopant ions are implanted into the bottom surfaces of the gate trenches. However, the sidewalls of the gate trenches typically are not perfectly vertical, but instead slope outwardly with increasing distance from the bottom of each gate trench. As a result, some p-type dopant ions will be directly implanted into the sidewalls of each gate trench during the ion implantation process. Additionally, some of the p-type dopant ions will bounce off the exposed portions of the n-type drift region that are underneath each gate trench, and some of these “reflected” p-type dopant ions will then implant into the sidewalls of the gate trenches. The implantation of p-type dopant ions into the sidewalls of the gate trenches through these two mechanisms during the ion implantation process that is performed to form the trench shielding regions may be problematic for two reasons.

First, the additional p-type dopant ions that are implanted into the sidewalls of the gate trenches act to increase the doping concentration of the p-type channel regions that are formed in these sidewalls. This may degrade the performance of the MOSFET since the p-type channel regions are typically doped to levels that optimize device performance. Second, the p-type ions that are implanted into the sidewalls can also convert the portions of the lightly-doped n-type drift region that form the lower portion of each sidewall into p-type material. If this occurs, the unit cells will no longer operate as transistors. While oxide spacers or other masks may be formed on the sidewalls of the gate trenches to prevent the p-type dopant ions from being implanted into the sidewalls during the ion implantation process, the use of such masks complicates the manufacturing process, and also limits the width of the trench shielding region with respect to the width of the gate trench.

Another potential problem with conventional techniques for forming trench shielding regions is that the trench shielding regions may not always be aligned perfectly with the gate trenches. If, for example, a trench shielding region is misaligned so that the center of the trench shielding region is offset to the left (e.g., by 0.1-0.6 microns) with respect to the center of its associated gate trench, then the trench shielding region may provide reduced protection to the portion of the gate oxide layer lining the lower right side of the gate trench. Consequently, higher electric fields will form in the gate oxide layer on the lower right side of the gate trench during device operation. When such misalignment is present, the voltage rating for the device be reduced and/or reduced device yields may become necessary (to reject devices with high misalignment levels).

Pursuant to embodiments of the present invention, gate trench power semiconductor devices are provided that include trench shielding patterns that are self-aligned with their respective gate trenches. The gate trench power semiconductor devices according to embodiments of the present invention may be fabricated by forming a mask structure on a suitable semiconductor layer structure, patterning the mask structure to expose regions where the gate trenches are to be formed, and then performing a high-energy ion implantation process to form trench shielding regions in portions of the semiconductor layer structure that will be underneath subsequently formed gate trenches. A portion of the mask structure may be removed, and the remaining mask material may then be used as an etch mask during a gate trench formation process. By using at least a portion of the same mask structure for both the trench shielding region ion implantation process and the gate trench etching process, the trench shielding regions may be self-aligned with the respective gate trenches.

In some embodiments, a multi-level mask structure may be used during the ion implantation process that is performed to form the trench shielding regions. The multi-level mask structure may comprise, for example, a first mask (e.g., a nitride, oxynitride or polysilicon mask) that is patterned to form openings above the regions in the semiconductor layer structure where the gate trenches will be formed. A second mask in the form of, for example, an oxide spacer is formed on the first mask (e.g., on the top surface of the first mask and on the sidewalls of the first mask that are exposed by the openings therein). The second mask acts to reduce the width of each of the openings in the first mask. The trench shielding region ion implantation process is performed with the full mask structure in place. The second mask may then be removed (or partially removed), which acts to widen the openings in the mask structure, and the etching process that is used to form the gate trenches may be performed. The thickness of the oxide spacer may be selected to optimize the width of each trench shielding region as compared to the width of its associated gate trench. This approach allows the trench shielding regions to be formed to extend well beyond the sidewalls of their associated gate trenches without using angled ion implants, while also self-aligning each trench shielding region with its associated gate trench.

In some embodiments, the ion implantation step used to form the trench shielding regions may be a high-energy ion implantation step that primarily implants the ions into portions of the semiconductor layer structure that are near or below the bottoms of the gate trenches that are formed in the semiconductor layer structure in a subsequent processing step. This may allow the use of a single implant step, and may also reduce the impact of the ion implantation step on the portions of the semiconductor layer structure that will ultimately serve as the channel regions of the device.

Since the ion implantation step that is used to form the trench shielding regions is performed before the gate trenches are formed, the problem of dopant ions implanting into non-vertical sidewalls of the gate trenches is eliminated, as is the potential for dopant ions to reflect off the bottoms of the gate trenches so that they implant into sidewalls of the gate trenches. Thus, the above-discussed problems where the doping concentration of the channel regions or the portions of the drift regions below the channel regions may be adversely impacted by unintended implantation into the sidewalls of the gate trenches may be avoided. Additionally, in at least some embodiments, the relative widths of the gate trenches and the trench shielding regions may be easily controlled by using a multi-layer mask structure. This allows a designer to optimize a tradeoff that exists between the specific on-resistance and the maximum electric field value in the gate oxide when the device is operated at its rated voltage level. This is important because in some applications, the limiting factor on device performance may be the maximum specific on-resistance value, whereas in other applications the limiting factor may be the maximum electric field value in the gate oxide (which acts to limit the voltage rating for the device). Thus, the techniques disclosed herein may allow a designer to fabricate devices that are optimized for different applications, which means that the present invention allows fabrication of devices that exhibit higher performance for various applications than could be provided using conventional fabrication techniques.

Pursuant to embodiments of the present invention, semiconductor devices that comprise a wide band-gap semiconductor layer structure are provided. The wide band-gap semiconductor layer structure comprises a drift region having a first conductivity type, a well region having a second conductivity type on the drift region, a source region having the first conductivity type on the well region, a gate electrode within a gate trench, and a trench shielding region having the second conductivity type underneath the gate trench. A width of the trench shielding region exceeds a width of the gate trench.

Pursuant to further embodiments of the present invention, semiconductor devices that comprise a wide band-gap semiconductor layer structure are provided where once again the wide band-gap semiconductor layer structure comprises a drift region having a first conductivity type, a well region having a second conductivity type on the drift region, a source region having the first conductivity type on the well region, a gate electrode within a gate trench, and a trench shielding region having the second conductivity type underneath the gate trench. A portion of the drift region having the first conductivity type is interposed between a bottom surface of the gate trench and the trench shielding region.

Pursuant to additional embodiments of the present invention, methods of fabricating a power semiconductor device are provided. Pursuant to certain of these methods, a first mask that includes a longitudinally-extending first opening that has a first width is formed on a semiconductor layer structure. A spacer is formed on sidewalls of the first mask that are exposed by the first opening to form a second mask, where the first and second masks comprise a mask structure that has a longitudinally-extending second opening that has a second width that is smaller than the first width. Dopants are implanted through the second opening to form an implanted region in the semiconductor layer structure. The spacer is at least partially removed from the sidewalls of the first mask to form a third opening in the mask structure. The semiconductor layer structure is then etched using the mask structure as an etch mask to form a gate trench in the semiconductor layer structure underneath the third opening

Pursuant to further embodiments of the present invention, methods of fabricating a power semiconductor device are provided in which a first mask is formed on a semiconductor layer structure, the first mask including a first opening. A spacer is formed on sidewalls of the first mask that are exposed by the first opening to form a second mask, the first and second masks comprising a mask structure that has a second opening. Dopants are implanted into the semiconductor layer structure through the second opening to form an implanted region in the semiconductor layer structure. The spacer is at least partially removed the sidewalls of the first mask. The semiconductor layer structure is then etched to form a gate trench that is self-aligned with the implanted region.

Pursuant to still further embodiments of the present invention, methods of fabricating a power semiconductor device are provided. Pursuant to these methods, a semiconductor layer structure is provided that comprises a drift region having a first conductivity type, a well region having a second conductivity type on the drift region, and a source region having the first conductivity type on the well region. A first mask is formed on the semiconductor layer structure, where the first mask including a first opening. Second conductivity type dopants are implanted into the semiconductor layer structure through at least a portion of the semiconductor layer structure that was exposed by the first opening to form an implanted region that has the second conductivity type in the drift region. After the second conductivity type dopants are implanted into the semiconductor layer structure, a portion of the source region that is exposed through the first opening still has the first conductivity type

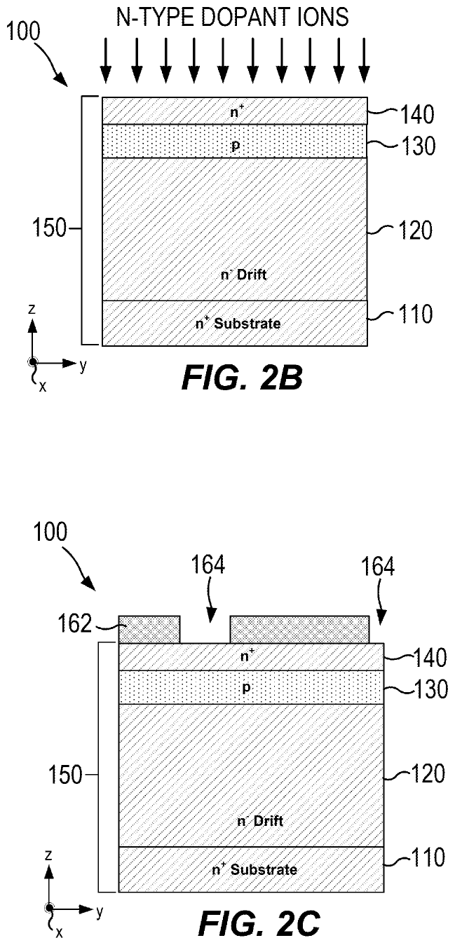

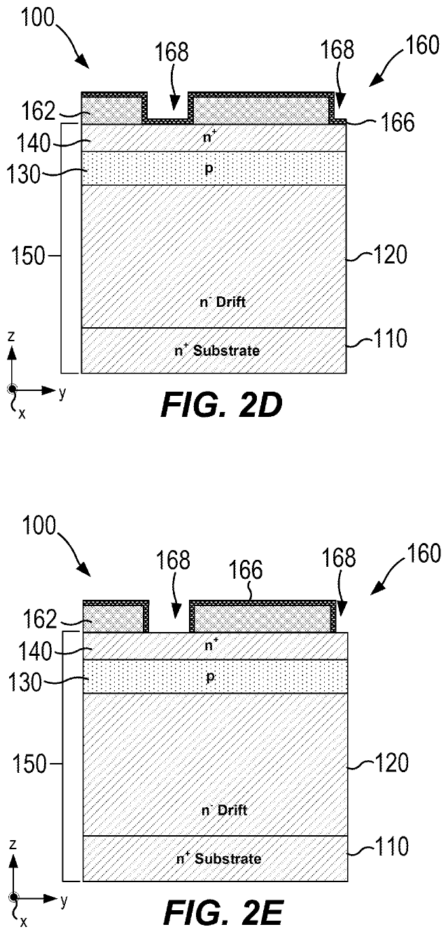

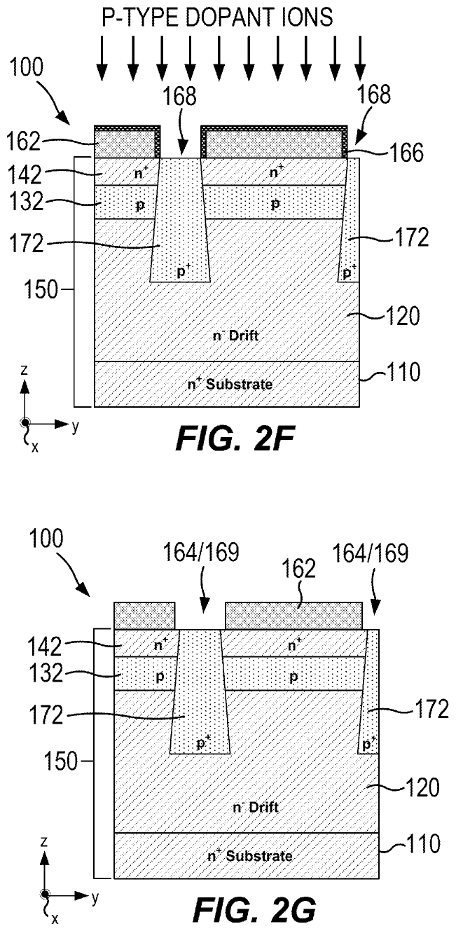

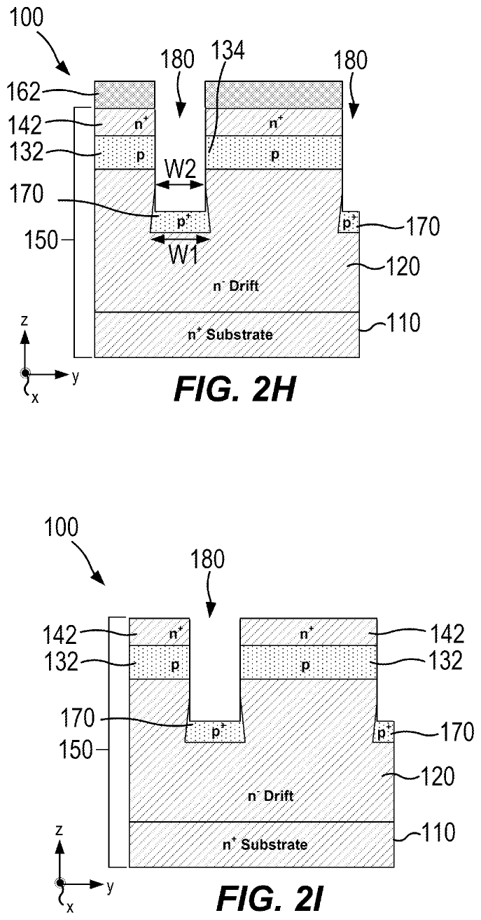

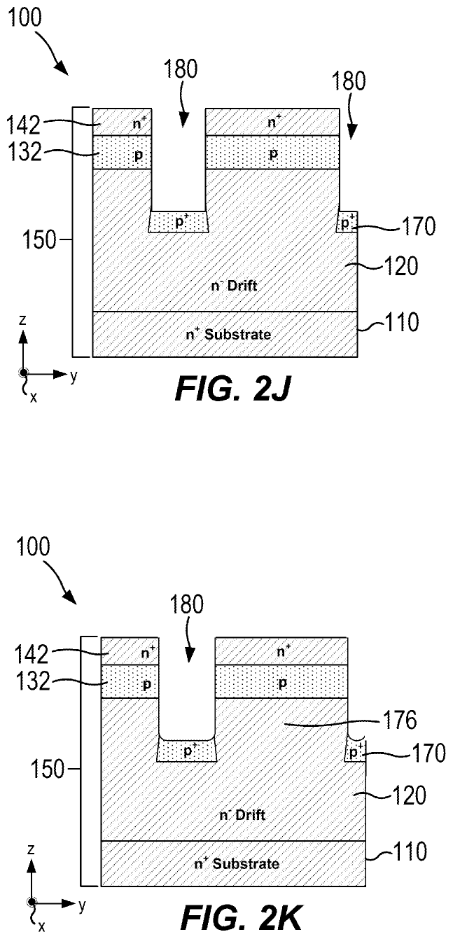

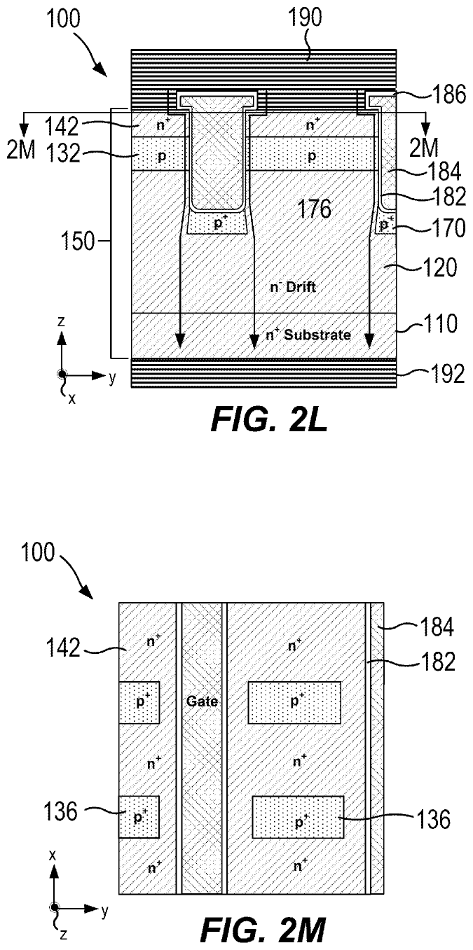

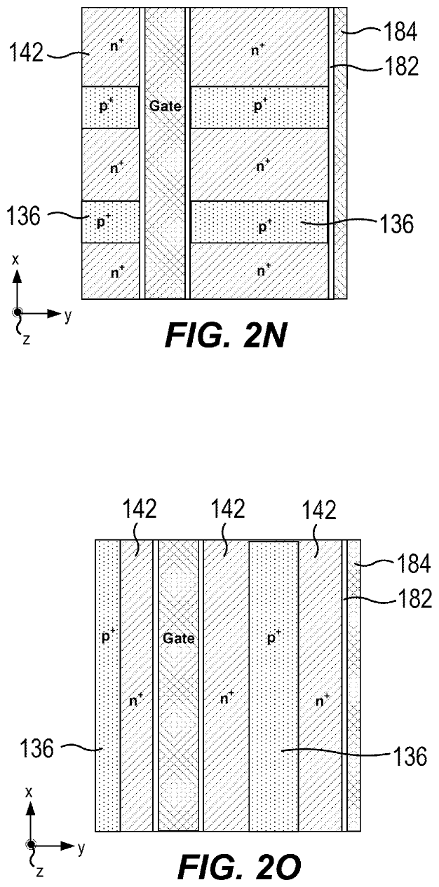

Embodiments of the present invention will now be described in more detail with reference to FIGS. 2A-8. It will be appreciated that features of the different embodiments disclosed herein may be combined in any way to provide many additional embodiments. Thus, it will be appreciated that various features of the present invention are described below with respect to specific examples, but that these features may be added to other embodiments and/or used in place of example features of other embodiments to provide many additional embodiments. Thus, the present invention should be understood to encompass these different combinations. Additionally, while the example embodiments focus on MOSFET implementations, it will be appreciated that the same techniques may be used in other gate trench power semiconductor devices such as insulated gate bipolar transistors (IGBTs), gate controlled thyristors and the like.

FIGS. 2A-2M are schematic cross-sectional views that illustrate a method of fabricating a gate trench power MOSFET 100 according to embodiments of the present invention. More specifically, FIGS. 2A-2L are schematic vertical cross-sectional views that illustrate the method of fabricating the semiconductor layer structure of the gate trench power MOSFET 100. FIG. 2M is a schematic horizontal cross-sectional view of MOSFET 100 taken along line 2M-2M of FIG. 2L. Herein, a vertical cross-sectional view of a power semiconductor device refers to a view of a cross-section taken through the device along a plane that is perpendicular to a major surface of the semiconductor layer structure of the device. Similarly, a horizontal cross-sectional view of a power semiconductor device refers to a view of a cross-section taken through the device along a plane that is parallel to a major surface of the semiconductor layer structure of the device.

Referring to FIG. 2A, an n-type silicon carbide substrate 110 is provided. The substrate 110 may comprise, for example, a 4H-silicon carbide or a 6H-silicon carbide substrate. In other embodiments, the substrate 110 may be or comprise a different semiconductor material (e.g., a Group III nitride-based material, silicon, gallium arsenide, zinc oxide, etc.). The substrate 110 may be heavily-doped (n⁺) with n-type impurities (i.e., an n⁺ silicon carbide substrate). The impurities may comprise, for example, nitrogen or phosphorous. Then-type doping concentration of the substrate 110 may be, for example, between 1×10¹⁸ atoms/cm³ and 1×10²¹ atoms/cm³, although other doping concentrations may be used. The substrate 110 may be relatively thick in some embodiments (e.g., 20-100 microns or more). It should be noted that while the substrates are shown in the figures as relatively thin layers, this is done to allow enlarging the thickness of other layers and regions in the figures, and it will be appreciated that the substrate 110 will typically be much thicker than shown. The thickness of various other layers of the MOSFETs according to embodiments of the present invention likewise may not be shown to scale in order to allow other portions of the devices to be enlarged in the figures.

A lightly-doped (n⁻) silicon carbide drift region 120 (which also may be referred to herein as a drift layer 120) is provided on an upper surface of the substrate 110. The n-type drift region 120 may be formed, for example, by epitaxial growth on the substrate 110. The n-type drift region 120 may have, for example, a doping concentration of 5×10¹⁵ to 5×10¹⁷ dopants/cm³. The n-type drift region 120 may be a thick region, having a vertical height above the substrate 110 of, for example, 3-50 microns. In some embodiments, an upper portion of the n-type drift region 120 may comprise an n-type current spreading layer (not shown) that is more heavily doped than the lower portion of the n-type drift region 120. If provided, the n-type current spreading layer may have a dopant concentration of, for example, 5×10¹⁶ to 1×10¹⁸.

Still referring to FIG. 2A, next, a moderately-doped (p) p-type silicon carbide well layer 130 is formed on the upper surface of the n-type drift region 120. The moderately-doped (p) p-type silicon carbide well layer 130 may be formed either by epitaxial growth or, as shown in FIG. 2A, by implanting p-type dopant ions into the upper portion of the n-type drift region 120 to convert the upper portion of the n-type drift layer into the p-well layer 130. The moderately-doped p-type well layer 130 may have a graded doping profile in some embodiments.

Referring to FIG. 2B, a heavily-doped (n⁺) silicon carbide source layer 140 is formed on the p-type silicon carbide well layer 130 or in upper portions of the p-type silicon carbide well layer 130. As shown, the heavily-doped n-type silicon carbide source layer 140 is typically formed via ion implantation. When formed by ion implantation, upper portions of the p-type silicon carbide well layer 130 are converted into the heavily-doped (n⁺) silicon carbide source layer 140. The heavily-doped n-type silicon carbide source layer 140 may have a doping concentration, for example, of between 1×10¹⁹ atoms/cm³ and 5×10²¹ atoms/cm³. While not visible in the cross-section of FIG. 2B (but see FIG. 2M), the n-type dopants may be selectively implanted into the p-type silicon carbide well layer 130 so that in selected regions the p-type well layer 130 will extend to the upper surface of the semiconductor layer structure 150. The substrate 110, the drift region 120, the well layer 130, and the source layer 140, along with the various regions/patterns formed therein such as trench shielding regions and trench shielding connection patterns (discussed below), comprise a semiconductor layer structure 150 of the power MOSFET 100.

Referring to FIG. 2C, a first mask 162 is formed on the supper surface of the source layer 140. The first mask 162 may comprise, for example, a nitride mask (e.g., silicon nitride) or an oxynitride mask (e.g., silicon oxynitride) or a multilayer mask such as a thin oxide (e.g., silicon oxide) layer with a nitride layer formed thereon. It will be appreciated, however, that a wide variety of other materials may be used. For example, the first mask 162 could comprise a polysilicon mask in other embodiments. As shown in FIG. 2C, the first mask 162 is then patterned (e.g., using standard photolithography patterning techniques) to form openings 164 that expose selected portions of the semiconductor layer structure 150. The openings 164 may be positioned above locations in the semiconductor layer structure 150 in which trench shielding regions will be formed in a subsequent processing step.

Referring to FIG. 2D, a second mask 166 in the form of a spacer is formed on the first mask 162 and the semiconductor layer structure 150. For example, the second mask 166 may be conformally formed on the first mask 162 and the semiconductor layer structure 150. Alternatively, the second mask 166 may be selectively deposited on the first mask 162 (and, as shown, may also optionally be formed on portions of the semiconductor layer structure 150 that are exposed by the openings 164 in the first mask 162). The first mask 162 and the second mask 166 together form a mask structure 160. The second mask 166 may comprise, for example, an oxide spacer (e.g., a silicon oxide spacer). Regardless as to how the second mask 166 is formed, the second mask/spacer 166 may conformally cover the sidewalls of the first mask 162 that are exposed by the openings 164. As such, the second mask/spacer 166 that is formed on the sidewalls of the first mask 162 reduces the size of the first openings 164, thereby forming second openings 168 in the mask structure 160. As shown, the second openings 168 may not extend completely through the mask structure 160 since the second mask may be formed on the exposed portions of the semiconductor layer structure 150. A thickness of the second mask 166 and, in particular, a thickness of the portions of the second mask 166 that are formed on sidewalls of the first mask 162 may be carefully controlled in order to control the width of each second opening 168.

Referring to FIG. 2E, the second mask 166 may be patterned to remove portions thereof that are formed on the semiconductor layer structure 150 in the second openings 168 (if such portions of the second mask 166 were formed in the first place) in order to expose selected portions of the semiconductor layer structure 150 in preparation for a subsequent ion implantation operation. It will be appreciated, however, that in some embodiments the patterning step illustrated with reference to FIG. 2E may be omitted and the portions of the second mask 166 that are formed on the semiconductor layer structure 150 in the second openings 168 may be left in place, and the ion implantation may be performed through these portions of the second mask 166.

Referring to FIG. 2F, an ion implantation process is performed to implant p-type dopant ions into the portions of the semiconductor layer structure 150 that are underneath the second openings 168. The combined thickness (herein “thickness” refers to the extent of something in the z-direction) of the first mask 162 and the second mask 166 may be sufficient to substantially block the p-type dopant ions that are implanted into portions of the mask structure 160 in which the first and second masks 162, 166 are vertically stacked from reaching the semiconductor layer structure 150. As shown in FIG. 2F, the ion implantation step forms a plurality of preliminary trench shielding regions 172 in the semiconductor layer structure 150. The preliminary trench shielding regions 172 may be heavily doped (p⁺) silicon carbide regions.

In example embodiments, the preliminary trench shielding regions 172 may have a doping concentration between about 1×10¹⁷ and 1×10²¹, and may extend to a depth of between 0.5 and 3.0 microns from the upper surface of the semiconductor layer structure 150. In other embodiments, the preliminary trench shielding regions 172 may have a doping concentration between about 1×10¹⁸ and 1×10²⁰, between about 1×10¹⁹ and 1×10²⁰, between about 1×10¹⁷ and 1×10²⁰, or between about 1×10¹⁸ and 1×10²¹. In other embodiments, the depth of the preliminary trench shielding regions 172 may be between 1.0 and 3.0 microns, between 1.0 and 2.5 microns, between 1.5 and 3.0 microns, between 1.5 and 2.5 microns, or between 0.5 and 2.5 microns. Any of the above dopant concentrations may be matched with any of the above-listed depths for the preliminary trench shielding regions 172. As shown, the preliminary trench shielding regions 172 extend through the silicon carbide source layer 140 and through the silicon carbide well layer 130 into the silicon carbide drift region 120. Trench shielding regions 170 (discussed below) that are formed from the preliminary trench shielding regions 172 in later processing steps may both act to reduce the electric field levels that form in gate oxide layers (discussed below) that are formed in gate trenches (discussed below) of the device during operation, as will be discussed in greater detail below.

As shown in FIG. 2F, the p-type dopant ions scatter to an extent as they strike protons and neutrons of the materials forming the semiconductor layer structure 150. This causes the preliminary trench shielding regions 172 to “bloom” in the sense that a width of the preliminary trench shielding regions 172 increases with increasing depth from the upper surface of the semiconductor layer structure 150.

This ion implantation step illustrated in FIG. 2F may implant at least some of the p-type dopant ions relatively deeply into the semiconductor layer structure 150. In the depicted embodiment, the p-type ions are shown as being implanted at a variety of depths into the semiconductor layer structure 150 so that sufficient p-type ions are implanted, for example, into the portions of the heavily-doped n⁺ source layer 140 and the lightly-doped n-type drift region 120 that are underneath the second openings 168 to convert these n-type regions into p-type material. Consequently, the preliminary trench shielding regions 172 may convert the moderately-doped p-type silicon carbide well layer 130 into a plurality of moderately-doped p-wells 132 and may convert the heavily-doped n-type silicon carbide source layer 140 into a plurality of heavily-doped n-type source regions 142 that serve as the source regions of the power MOSFET 100.

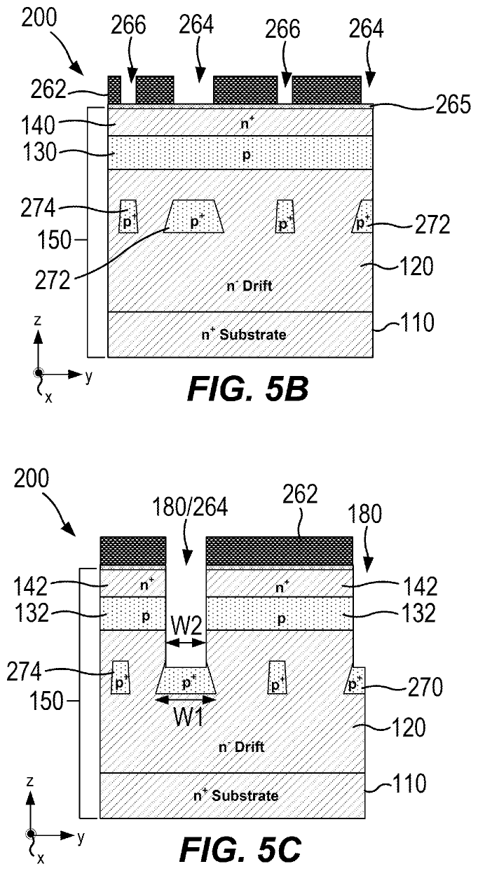

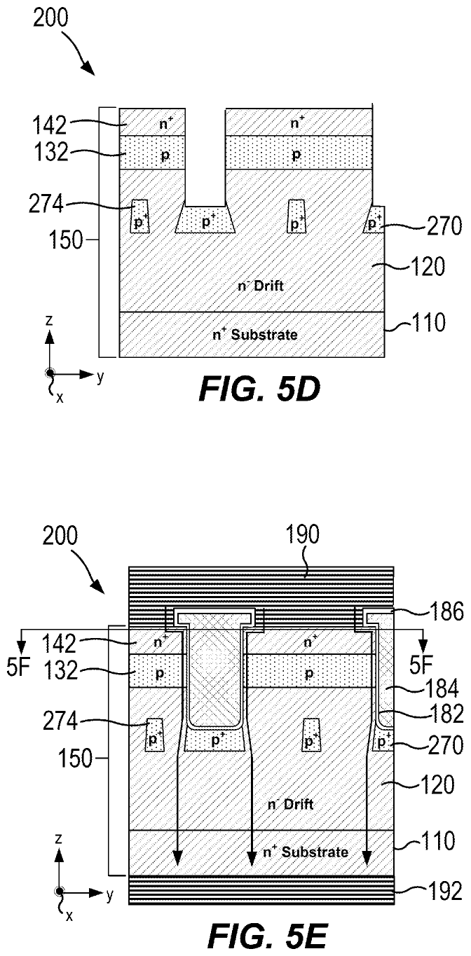

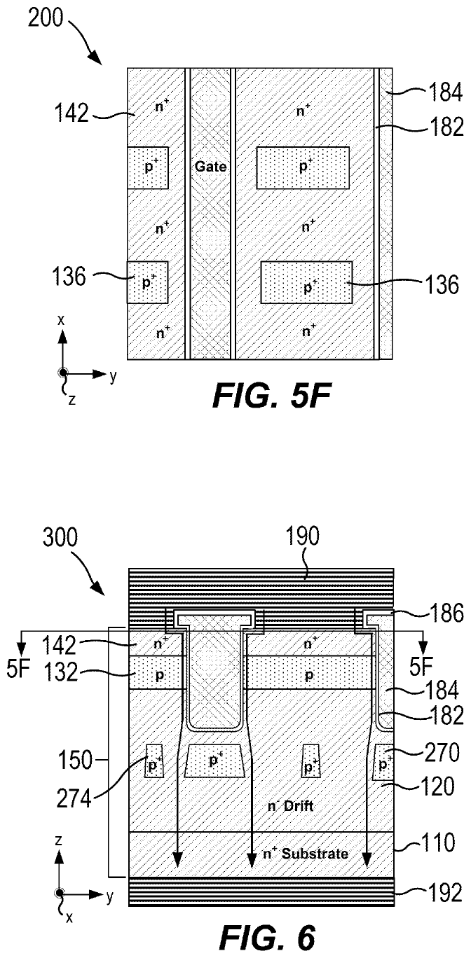

As will be discussed below with reference to FIGS. 5A-5F, in some embodiments of the present invention, so-called “deep” ion implantation techniques may be used where the ions are implanted at high energies such that almost all of the ions are implanted through the source layer 140 and the p-well 130. When such deep ion implantation techniques are used, the heavily-doped n⁺ source layer 140 and the portions of the drift region 120 that are below the p-well layer 130 underneath the second openings 168 (which portions of the drift region 120 is removed when the gate trenches are formed) may remain n-type material. It will be appreciated that either type of ion implantation process may be used here. In other words, in other embodiments, the deep ion implantation techniques discussed below with reference to FIGS. 5A-5F may be used in place of the “shallow and deep” ion implantation technique shown in FIG. 2F.

Referring to FIG. 2G, the second mask 166 is at least partially removed after the preliminary trench shielding regions 172 are formed to convert the second openings 168 into third openings 169 that are wider than the second openings 168. In the depicted embodiment, the second mask 166 is completely removed, so that the only remaining mask on the device is the first mask 162. In this case, the third openings 169 are identical to the first openings 164 therein. The third openings 169 expose the preliminary trench shielding regions 172 and portions of the source regions 142 in the semiconductor layer structure 150. In other embodiments (not shown), the second mask 166 may be thinned but not completely removed. In such embodiments, the third openings 169 are wider than the second openings 168 but narrower than the first openings 164.

Referring to FIG. 2H, a plurality of gate trenches 180 are formed via etching in an upper surface of the semiconductor layer structure 150 using the remaining mask structure 160 (here the first mask 162) as an etch mask. Each gate trench 180 extends into an upper surface of the n-type drift region 120. Although only one full gate trench 180 and a portion of a second gate trench 180 are shown in FIG. 2H, it will be appreciated that a large number of gate trenches 180 are typically provided, where a longitudinal axis of each gate trench 180 extends in a first direction above the substrate 110 (here the gate trenches 180 extend in the x-direction), and the gate trenches 180 are spaced apart from each other in a second direction (here the y-direction) so that the gate trenches 180 extend longitudinally in parallel to each other. Each gate trench 180 has a length (corresponding to a distance in the x-direction), a width (corresponding to a distance in the y-direction), and a depth (corresponding to a distance in the z-direction). The length direction is the longest direction, and hence the longitudinal axis of each gate trench 180 refers to an axis that extends in the length direction down the middle of the gate trench 180. Each gate trench 180 has first and second opposed sidewalls and a bottom surface that each extend in the x-direction and hence extend parallel to the longitudinal axis. Herein, references to a “width” of a gate trench 180 refer to the shortest distance between the opposed longitudinal sidewalls of the gate trench 180 (i.e., the shortest distance between the opposed longitudinal sidewalls in the y-direction).

As noted above, if the preliminary trench shielding regions 172 extend to the upper surface of the semiconductor layer structure 150, formation of the preliminary trench shielding regions 172 acts to convert the moderately-doped p-type silicon carbide well layer 130 into a plurality of moderately-doped p-wells 132 and to convert the heavily-doped n-type silicon carbide source layer 140 into a plurality of heavily-doped n-type source regions 142. In cases where only a high-energy ion implantation process is used so that the preliminary trench shielding regions 172 are formed as deep buried regions (see discussion of FIGS. 5A-5F below), the formation of the gate trenches 180 acts to convert the moderately-doped p-type silicon carbide well layer 130 into a plurality of moderately-doped p-wells 132 and to convert the heavily-doped n-type silicon carbide source layer 140 into a plurality of heavily-doped n-type source regions 142. In either case, the portions of each p-well 132 that are adjacent the gate trenches 180 act as transistor channels 134, as will be discussed below.

While FIG. 2H illustrates a MOSFET 100 that has a plurality of gate trenches 180 that all extend in parallel to each other in a first direction, it will be appreciated that embodiments of the present invention are not limited thereto. Power MOSFETs having a wide variety of gate trench designs are known in the art. For example, some power MOSFETs have both a first set of gate trenches that extend in a first direction through a semiconductor layer structure and a second set of gate trenches that extend through the semiconductor later structure in a second (typically perpendicular) direction so that the trenches in the two sets intersect each other. As another example, some MOSFETs have gate trenches formed in rectangular, hexagonal, octagonal or circular shapes (when viewed from above) where the trenches surround well regions (with source regions therein). It will be appreciated that the techniques disclosed herein may be used on MOSFETs having any gate trench designs, including the example additional designs discussed above.

The etching step that is performed to form the gate trenches 180 removes the upper portion of each preliminary trench shielding region 172, thereby forming a plurality of trench shielding regions 170 underneath the respective gate trenches 180. In the depicted embodiment, each gate trench 180 is narrower (in the width direction) than the associated trench shielding region 170 that is provided underneath the gate trench 180. Consequently, each trench shielding region 170 extends onto the lower sidewalls of its associated gate trench 180. Since the width of the second mask 166 that is formed on the sidewalls of the first mask 162 may be set to any desired value, the width W2 of each gate trench 180 relative to the width W1 its associated trench shielding region 170 may be set to any desired value. As noted above, FIG. 2H illustrates an embodiment where the width W1 of the trench shielding region 170 (as measured at a depth of the bottom of the gate trench 180) is slightly wider than the width W2 of its associated gate trench 180.

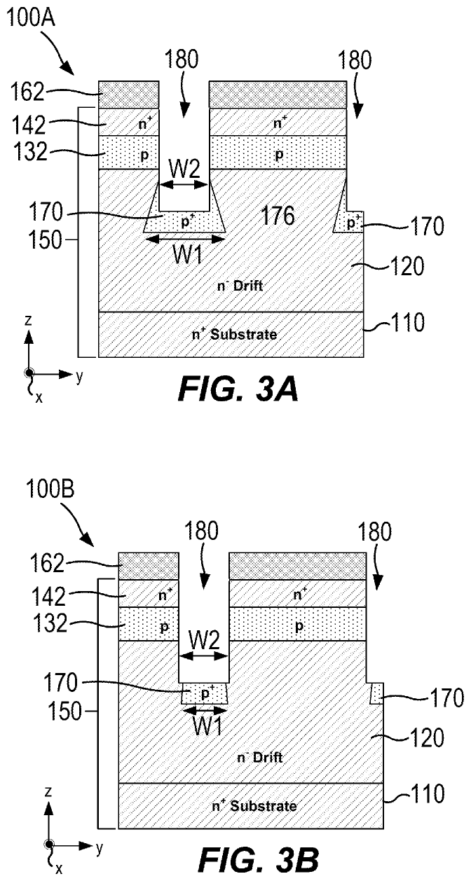

FIG. 3A is a cross-section (corresponding to the cross-section of FIG. 2H) of a MOSFET 100A according to further embodiments of the present invention where the width of the second mask 166 on the sidewalls of the first mask 162 was reduced from that shown in FIGS. 2D-2F. As can be seen from FIG. 3A, this causes of the trench shielding region 170 to have a width W1 (as measured at the depth of the bottom of its associated gate trench 180) that is significantly wider than the width W2 of its associated gate trench 180.

In contrast, FIG. 3B is a cross-section (corresponding to the cross-section of FIG. 2H) of a MOSFET 100B according to further embodiments of the present invention where the width of the second mask 166 on the sidewalls of the first mask 162 was increased from that shown in FIGS. 2D-2F. As can be seen from FIG. 3B, this results in the trench shielding region 170 having a width W1 (as measured at the depth of the bottom of its associated gate trench 180) that is narrower than the width W2 of its associated gate trench 180.

In the embodiments of FIGS. 2H and 3A, the gate trench 180 has left and right sidewalls that extend in parallel to a longitudinal axis of the gate trench 180, the left and right sidewalls spaced apart from each other in a lateral direction. In some embodiments, a left side of the trench shielding region 170 may extend laterally beyond the lower edge of the left sidewall of the gate trench by at least 0.1 microns, and the right side of the trench shielding region extends laterally beyond the lower edge of the right sidewall of the gate trench by at least 0.1 microns. In other embodiments, a left side of the trench shielding region 170 may extend laterally beyond the lower edge of the left sidewall of the gate trench by at least 0.3 microns, and the right side of the trench shielding region extends laterally beyond the lower edge of the right sidewall of the gate trench by at least 0.3 microns. In still other embodiments, a left side of the trench shielding region 170 may extend laterally beyond the lower edge of the left sidewall of the gate trench by at least 0.4 microns, and the right side of the trench shielding region extends laterally beyond the lower edge of the right sidewall of the gate trench by at least 0.4 microns.

In some embodiments, a left side of the trench shielding region 170 may extend laterally beyond the lower edge of the left sidewall of the gate trench and the right side of the trench shielding region may extend laterally beyond the lower edge of the right sidewall of the gate trench by between 0.1 microns and 0.8 microns each. In other embodiments, the left side of the trench shielding region 170 may extend laterally beyond the lower edge of the left sidewall of the gate trench and the right side of the trench shielding region may extend laterally beyond the lower edge of the right sidewall of the gate trench by between 0.1 microns and 0.6 microns each. In still other embodiments, the left side of the trench shielding region 170 may extend laterally beyond the lower edge of the left sidewall of the gate trench and the right side of the trench shielding region may extend laterally beyond the lower edge of the right sidewall of the gate trench by between 0.1 microns and 0.5 microns each. In yet additional embodiments, the left side of the trench shielding region 170 may extend laterally beyond the lower edge of the left sidewall of the gate trench and the right side of the trench shielding region may extend laterally beyond the lower edge of the right sidewall of the gate trench by between 0.2 microns and 0.5 microns each. It should be noted that the left side of the trench shielding region 170 may extend laterally beyond the lower edge of the left sidewall of the gate trench a different amount than the right side of the trench shielding region extends laterally beyond the lower edge of the right sidewall of the gate trench in some embodiments.

In some embodiments, the gate trench may overlap less than 98% of a lateral width of the trench shielding region. In this context, “overlap” means that in a vertical cross-section such as FIG. 2H the bottom of the gate trench 180 is over top of the trench shielding region 170. Thus, for example, if in FIG. 2H width W2 is 8 arbitrary units and width W1 is 10 arbitrary units, then the gate trench overlaps 80% of a lateral width of the trench shielding region 170. In other embodiments, the gate trench may overlap less than 95%, less than 90% or less than 85% of the lateral width of the trench shielding region 170.

Referring to FIG. 2I, the remaining portion of the mask structure 160 may be removed. If the remaining portion of the mask structure 160 is the first mask 162 and is formed as a nitride mask, then a stripping operation may be used to remove the first mask 162.

Referring to FIG. 2J, a sacrificial oxidation process may be performed that converts exposed portions of the semiconductor layer structure 150 into silicon oxide. The “depth” to which the exposed silicon carbide is converted into silicon oxide may be controlled based on the length of the oxidation process, the temperature thereof, the pressure, and the amount of oxygen in the environment. An etching process is then performed to remove the oxidized silicon carbide. This sacrificial oxidation process may be used remove surface portions of the silicon carbide that may have been damaged during the ion implantation process (e.g., roughened). The sacrificial oxidation process may also widen the gate trenches 180, as shown. In the depicted embodiment, the gate trenches 180 are widened so that their associated trench shielding regions 170 only extend to a very small extent onto the lower sidewalls of the gate trenches 180. It will be appreciated that in other embodiments the trench shielding regions 170 may be designed so that the trench shielding regions 170 are formed thicker on the lower sidewalls of their associated gate trenches 180 and/or extend further up the lower sidewalls of their associated gate trenches 180 (see, e.g., FIG. 3A).

Referring to FIG. 2K, a hydrogen etch may be performed. The hydrogen etch may further widen the gate trenches 180 and etch the upper surface of the semiconductor layer structure 150. The hydrogen etch may also advantageously round the lower corners of each gate trench 180 (note that these “corners” extend the full length of each gate trench 180 in the x-direction). The rounding of the lower corners of each gate trench 180 is transferred to the gate oxide layers that are formed in each respective gate trench 180 during a subsequent processing operation (see FIG. 2L), such that the gate oxide layer that is formed in the corners of each trench 180 also has a rounded cross-sectional profile. The rounding of these gate oxide layers acts to reduce the electric field levels in the lower corners of the gate oxide layers during reverse blocking operation, as it reduces electric field crowding effects that occur in layers having sharp corners. This reduction in the electric field values may allow for higher voltage ratings for the power semiconductor devices according to embodiments of the present invention. While not shown in the figures, the hydrogen etch may also act to round the upper corners of each gate trench 180. Such rounding of the upper corners of the gate trenches 180 may reduce electric field values in upper portions of the gate oxide layers during on-state operation, which also is advantageous.

After the hydrogen etch is performed, an annealing process may be performed that activates the p-type dopants in the trench shielding regions 170.

Referring to FIG. 2L, a gate insulating layer 182 is formed on the bottom surface and sidewalls of each gate trench 180. Typically, the gate insulating layers 182 are oxide layers and hence will be referred to as gate oxide layers 182 herein. The gate oxide layer 182 may be formed by forming an oxide layer conformally on the bottom surface and sidewalls of each gate trench 180. The conformal gate oxide layer 182 may be formed by oxidizing the exposed silicon carbide via an anneal in an oxygen containing environment. Alternatively, the conformal gate oxide layer 182 may be formed by an oxide deposition step. Portions of the conformal gate oxide layer 182 may be removed to form openings where a source contact 190 can connect to the source regions 142 and to p-well extensions (discussed below). Removal of these portions of the conformal gate oxide layer 182 leaves a gate oxide layer 182 in each gate trench 180.

A gate electrode 184 is formed on each gate oxide layer 182 to fill the respective gate trenches 180. The gate electrodes 184 may each comprise a conductive material such as, for example, polysilicon, a silicate or a metal. Inter-metal dielectric layers 186 are formed on the exposed portions of the gate oxide layers 182 and the gate electrodes 184. A source contact 190 is formed on the upper portion of the device. The source contact 190 is physically and electrically connected to the n-type source regions 142. The source contact 190 may comprise the source terminal of the MOSFET 100 or may be electrically connected to the source terminal. While not visible in the cross-section of FIG. 2L, p-well extensions 136 may be formed in the MOSFET 100 that physically and electrically connect the p-wells 132 to the source contact 190 in selected regions of the device. These p-well extensions 136 are illustrated in the plan view of FIG. 2M, and methods of forming these p-well extensions are known in the art. In addition, trench shield connection regions (not shown) may be provided in either the active area and/or an inactive area of the MOSFET 100 that electrically connect the p-wells 132 to the trench shielding regions 170. A drain contact 192 is formed on the lower surface of the substrate 110. A gate contact (not shown) is also provided that is connected to the gate electrodes 184 outside the view of the cross-section of FIG. 2L, typically via one or more gate buses (not shown).

As discussed above, the portion of each p-well 132 that is adjacent a gate trench 180 acts as a vertical transistor channel 134. Thus, when a sufficient gate bias voltage is applied, current will flow from the source contact 190 to the drain contact 192 along the current paths illustrated by the arrows in FIG. 2L.

FIG. 2M is a horizontal cross-section taken through the device shown in FIG. 2L along line 2M-2M (i.e., the cross-section is taken along the top surface of the semiconductor layer structure 150). FIG. 2M shows how the p-well extensions 136 may comprise a series of islands that extend upwardly through the source regions 142 to the upper surface of the semiconductor layer structure 150. The p-well extensions 136 may be highly-doped (p⁺) p-type regions. The p-well extensions 136 electrically connect the p-wells 132 to the source contact 190. It will be appreciated that FIG. 2M illustrates one possible design where the p-well extensions 136 are formed as islands in the source regions 142 when viewed from above. Other designs are possible. For example, FIG. 2N illustrates a modified version of MOSFET 100 where the p-well extensions 136 are formed as horizontal stripes. FIG. 2O illustrates another modified version of MOSFET 100 where the p-well extensions 136 are formed as vertical stripes within the source regions 142.

The trench shielding regions 170 help protect the corners of the gate oxide layers 182 from high electric fields during reverse blocking operation. However, a tradeoff exists between the specific on-resistance of MOSFET 100 and the maximum electric field value that may occur in the gate oxide layers 182. In particular, the trench shielding regions 170 create a so-called JFET region 176 in the drift layer. The current flows from the source contact 190, through the channel 134 and then into this JFET region 176 on its path to the drain contact 192. If the trench shielding regions 170 are wider than the gate trenches 180, then the trench shielding regions 170 that are associated with adjacent gate trenches 180 act to narrow the width of the JFET region 176, which acts to increase the specific on-resistance of the MOSFET 100 (since the current is now forced through a narrower region). This can be seen, for example, with reference to FIG. 3A (described above), where the trench shielding regions 180 are significantly wider than the gate trenches 180. In some applications, a low on-resistance may be more important than a high voltage rating. In such embodiments, it may be beneficial to keep the widths W1 of the trench shielding regions 170 to be less than or equal to the widths W2 of their associated gate trenches 180.

Since the thickness of the second mask 166 that is formed on the sidewalls of the first mask 162 may be carefully controlled, the methods of forming power semiconductor devices disclosed herein allow for the relative widths of the trench shielding regions 170 and the gate trenches 180 to be carefully controlled, so that each trench shielding region 170 may extend to any desired width beyond the sidewalls of its associated gate trench 180. The methods described herein also allow a designer to easily account for the widening of the gate trenches 180 that may occur during the above-discussed sacrificial oxidation and/or hydrogen etching processing steps. In some applications, the specific on-resistance may be the limiting factor, while in other applications, the voltage rating may be more important. The techniques disclosed herein allow a designer to easily optimize the relative widths of the trench shielding regions 170 and the gate trenches 180 in order to optimize performance for any particular application.

Another potential problem in the fabrication of gate trench power semiconductor devices is that the trench shielding regions and the gate trenches of the device may be misaligned. In some conventional fabrication techniques, different masks are used for the ion implantation step that is used to form the trench shielding regions and for the etching step that is used to form the gate trenches. If the second of these masks is not perfectly aligned with the position of the first mask, then the trench shielding regions 170 will be laterally (i.e., in the y-direction) misaligned with respect to the respective gate trenches 180. If this occurs, then on one side of each gate trench 180, the trench shielding region 170 will extend laterally beyond the gate trench 180, acting to narrow the JFET region 176, resulting in an increase in the on-resistance. The problem of such lateral misalignment in conventional power semiconductor devices can be reduced or eliminated by decreasing the widths of the trench shielding regions 170. However, as discussed above, decreasing the width of the trench shielding region 170 reduces its effectiveness, and hence may reduce the voltage rating for the MOSFET 100 in order to keep the electric fields that develop in the gate oxide layer at levels that will not degrade the gate oxide. As described above, the techniques according to embodiments of the present invention automatically self-align each trench shielding region 170 with its associated gate trench 180, thereby avoiding the performance degradations associated with mis-aligned trench shielding regions 170.

It will be appreciated that the processing steps discussed above with reference to FIGS. 2A-2M could be performed in different orders in further embodiments. As an example, the hydrogen etching step that is discussed with reference to FIG. 2J could be performed before the sacrificial oxidation step that is discussed with reference to FIG. 2K. It will also be appreciated that some of the processing steps (e.g., the hydrogen etching step, the sacrificial oxidation, etc.) could be omitted in other embodiments.

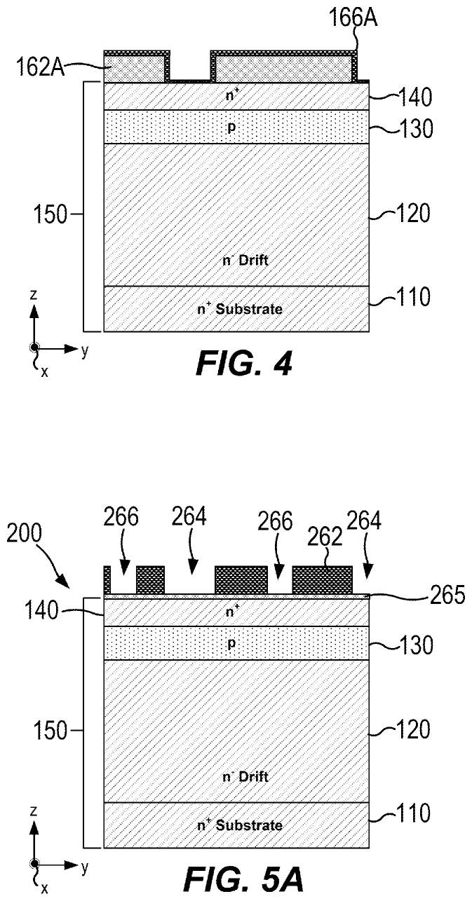

FIGS. 2A-2M illustrate a method for forming a MOSFET 100 in which a spacer (e.g., an oxide spacer) is deposited as a second mask 166 on a patterned first mask 162. Pursuant to further embodiments of the present invention, a second mask 166A may instead be formed by oxidizing a first mask 162A. This is schematically shown in FIG. 4, which is corresponds to FIG. 2D.

As shown in FIG. 4, in embodiments of the present invention that form the second mask 166A by oxidation, a material that readily oxidizes such as polysilicon may be used to form the first mask 162A. Once the first mask 162A is patterned as discussed above with reference to FIG. 2D, the second mask 166A may be formed by performing an oxidizing process on the device (e.g., heating the device in an oxygen-containing environment). Since polysilicon oxidizes more readily than silicon carbide, a second mask 166A is formed that is thicker on the upper surface and sidewalls of the polysilicon first mask 162A than it is on the exposed portions of the upper surface of the semiconductor layer structure 150. As discussed above with reference to FIG. 2E, the oxidized material that is formed on the exposed portions of the upper surface of the semiconductor layer structure 150 may then be removed or may be left in place so that the ion implantation step discussed above with reference to FIG. 2F is performed through the oxidized silicon carbide material. The device shown in FIG. 4 may then be fabricated using the same processing steps that are discussed above with reference to FIGS. 2D-2M, and hence further description thereof will be omitted here.

FIGS. 5A-5F are schematic cross-sectional views that illustrate a gate trench power MOSFET 200 according to further embodiments of the present invention. More specifically, FIGS. 5A-5E are schematic vertical cross-sectional views that illustrate a method of fabricating the semiconductor layer structure of MOSFET 200. FIG. 5F is a schematic horizontal cross-sectional view of MOSFET 200 taken along line 5F-5F of FIG. 5E.

Referring to FIG. 5A, an optional spacer (e.g., a nitride spacer) 265 may be formed on the upper surface of a semiconductor layer structure 150. The semiconductor layer structure 150 may be formed in the manner discussed above with reference to FIGS. 2A-2B. A mask 262 is then formed on the spacer 266 (or on the upper surface of a semiconductor layer structure 150 if the spacer 266 is not provided). The mask 262 may comprise, for example, an oxide mask (e.g., silicon oxide). The mask 262 is patterned (e.g., using standard photolithography patterning techniques) to form openings 264 and 266 that expose selected portions of the semiconductor layer structure 150. The openings 264 may be positioned above locations in the semiconductor layer structure 150 in which trench shielding regions will be formed in a subsequent processing step. The openings 266 may be positioned above locations in the semiconductor layer structure 150 in which trench support shields will be formed in a subsequent processing step. It will be appreciated that in some embodiments the trench support shields may be omitted. In such embodiments, the openings 266 are not formed in the mask 262.

Referring to FIG. 5B, a high-energy “deep” ion implantation process is performed to implant p-type dopant ions through the openings 264, 266. Due to the high-energy level of the implant, most of the p-type ions are implanted through the source layer 140, the p-well layer 130 and into the drift region 120. As such, the source layer 140 may remain n-type after the ion implantation step is performed, and in some cases, the portion of the drift layer 120 that is immediately below the p-well layer 130 may also remain n-type after the ion implantation process is completed. As shown in FIG. 5B, the ion implantation process forms a plurality of buried preliminary trench shielding regions 272 in the semiconductor layer structure 150. The preliminary trench shielding regions 272 may be heavily doped (p⁺) silicon carbide regions having any of the doping concentrations listed above for the preliminary trench shielding regions 172. The preliminary trench shielding regions 272 likewise may extend to any of the depths listed above for the preliminary trench shielding regions 172. As is further shown in FIG. 5B, the ion implantation process also forms a plurality of buried trench support shields 274 in the semiconductor layer structure 150. The trench support shields 274 (if included in the device) may be heavily doped (p⁺) silicon carbide regions. The trench support shields 274 may act to reduce the electric field levels that form in the gate oxide layers (discussed below) during device operation. The trench support shields 274 may also provide a low-resistance current path between the source and drain terminals of the MOSFET 200 if avalanche breakdown occurs. This lower resistance current path helps reduce the amount that the device heats up during an avalanche breakdown event, increasing the likelihood that the MOSFET 200 can survive such an event without damage.

As can also be seen from FIG. 5B, the p-type dopant ions scatter to an extent as they strike protons and neutrons of the materials forming the semiconductor layer structure 150. This causes the preliminary trench shielding regions 272 and the trench support shields 274 to “bloom” in the sense that a width of these regions 272 increases with increasing depth from the upper surface of the semiconductor layer structure 150. Note that in the example of FIG. 5B, mask 262 is used as an etch mask for forming both the preliminary trench shielding regions 172 and the trench support shields 274. It will be appreciated that in other embodiments, separate masks and ion implantation steps may be used for forming the preliminary trench shielding regions 172 and the trench support shields 274. In such embodiments, the preliminary trench shielding regions 172 may, for example, be formed using a high-energy “deep” ion implantation process (and hence will have the shapes shown in FIG. 5B), while the trench support shields 274 may be formed using a shallow and deep ion implantation process. This may allow the trench support shields 274 to extend farther toward the upper surface of the semiconductor layer structure 150 so that the trench support shields 274 physically and electrically connect to the p-well layer 130.

Referring to FIG. 5C, additional mask material may be formed that fills in the openings 266 in the mask structure while leaving the openings 264. For example, a selective oxide deposition may be performed to fill in the openings 266. Next, a plurality of gate trenches 180 are formed via etching in an upper surface of the semiconductor layer structure 150. The gate trenches 180 are formed using mask 262 as an etch mask. Each gate trench 180 extends into an upper surface of the n-type drift region 120. Although only one full gate trench 180 and a portion of a second gate trench 180 are shown in FIG. 5C, it will be appreciated that a large number of gate trenches 180 are typically provided, as discussed above with reference to MOSFET 100. The gate trenches 180 convert the moderately-doped p-type silicon carbide well layer 130 into a plurality of moderately-doped p-wells 132 and convert the heavily-doped n-type silicon carbide source layer 140 into a plurality of heavily-doped n-type source regions 142. The portions of each p-well 132 that are adjacent the gate trenches 180 act as transistor channels 134. While FIG. 5C illustrates a device that has a plurality of gate trenches 180 that all extend in parallel to each other in a first direction, as discussed above with reference to MOSFET 100, embodiments of the present invention are not limited thereto.

The etching step that is performed to form the gate trenches 180 may remove the upper portion of each preliminary trench shielding region 272, thereby forming a plurality of trench shielding regions 270 underneath the respective gate trenches 180.

Referring to FIG. 5D, the mask 262 and the optimal spacer 265 may be removed. Thereafter, a sacrificial oxidation process and/or a hydrogen etch may be performed. As these processes may be identical to the processes discussed above with reference to FIGS. 2J-2K, further description thereof will be omitted here. Thereafter, an annealing process may be performed that activates the p-type dopants in the trench shielding regions 270.

As shown in FIG. 5E, a gate oxide layer 182, gate electrodes 184, inter-metal dielectric layers 186, a source contact 190 and a drain contact 192 are formed in the manner discussed above with reference to FIG. 2L to form the MOSFET 200. The MOSFET 200 may also include p-well extensions 136 that physically and electrically connect the p-wells 132 to the source contact 190. These p-well extensions 136 are illustrated in the plan view of FIG. 5F. In addition, trench shield connection regions (not shown) may be provided in either the active area and/or an inactive area of the MOSFET 200 that electrically connect the p-wells 132 to the trench shielding regions 170.

FIG. 5F is a horizontal cross-section taken through the device as shown in FIG. 5E along line 5F-5F (i.e., the cross-section is taken along the top surface of the semiconductor layer structure 150. FIG. 5F shows how the p-well extensions 136 may comprise a series of islands that extend upwardly through the source regions 142 to the upper surface of the semiconductor layer structure 150. The p-well extensions 136 may be highly-doped (p⁺) p-type regions. The p-well extensions 136 electrically connect the p-wells 132 to the source contact 190.

The upper surfaces of the preliminary trench shielding regions 272 of MOSFET 200 are formed at a depth from the top surface of the semiconductor layer structure 150 that is less than a depth of the gate trenches 180. As a result the etching step that is performed to create the gate trenches 180 (see FIG. 5C) removes the upper portion of each preliminary trench shielding region 272 to form the trench shielding regions 270. It will be appreciated, however, that in further embodiments of the present invention, MOSFETs may be provided in which the preliminary trench shielding regions 272 are formed so that the upper surfaces thereof are at depths in the semiconductor layer structure 150 that are below the depths of the bottom of the gate trenches 180. In such MOSFETs, formation of the gate trenches does not alter the preliminary trench shielding regions 272 and hence the trench shielding regions 270 may be identical to the preliminary trench shielding regions 272. FIG. 6 is a schematic cross-sectional view of a MOSFET 300 that has this configuration.

As can be seen, the MOSFET 300 of FIG. 6 is very similar to the MOSFET 200 of FIG. 5E, with the difference being that the trench shielding regions 270 and the trench support shields 274 are formed deeper in the semiconductor layer structure 150. Because of this change, a portion of the lightly-doped n-type drift region 120 is interposed between each trench shielding region 270 and its associated gate trench 180. This design may further help protect the gate oxide layers 182 lining the bottoms of the respective gate trenches 180 as the trench shielding regions extend deeper into the semiconductor layer structure 150.

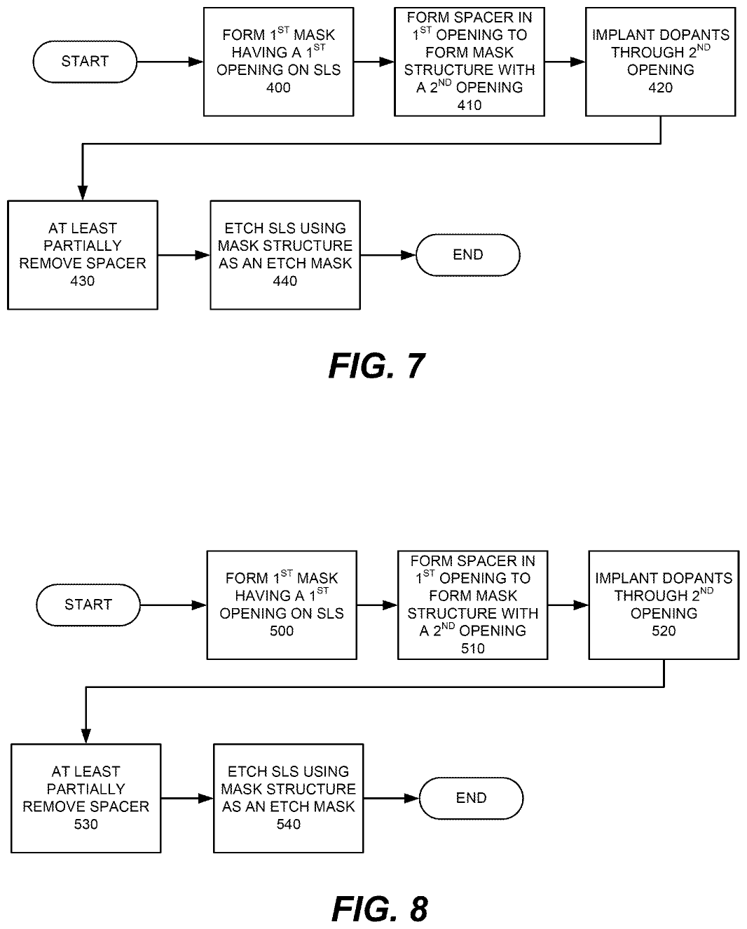

FIG. 7 is a flow chart illustrating a method according to embodiments of the present invention for fabricating a gate trench semiconductor device such as, for example, a power wide band-gap gate trench semiconductor device.

As shown in FIG. 7, a first mask is formed on a semiconductor layer structure (“SLS”) (Operation 400). The first mask includes a longitudinally-extending first opening that has a first width. A spacer is formed on sidewalls of the first mask that are exposed by the first opening to form a second mask (Operation 410). The first and second masks comprise a mask structure that has a longitudinally-extending second opening that has a second width that is smaller than the first width. Dopants are implanted into the semiconductor layer structure through the second opening to form an implanted region in the semiconductor layer structure (Operation 420). Then, the spacer is at least partially removed from the sidewalls of the first mask to form a third opening in the mask structure (operation 430). The semiconductor layer structure is then etched using the mask structure as an etch mask to form a gate trench in the semiconductor layer structure underneath the third opening (Operation 440).

FIG. 8 is a flow chart illustrating a method according to further embodiments of the present invention for fabricating a gate trench semiconductor device such as, for example, a power wide band-gap gate trench semiconductor device.

As shown in FIG. 8, a first mask is formed on a semiconductor layer structure, the first mask including a first opening (Operation 500). A spacer is formed on sidewalls of the first mask that are exposed by the first opening to form a second mask, the first and second masks comprising a mask structure that has a second opening (Operation 510). Dopants are implanted into the semiconductor layer structure through the second opening to form an implanted region in the semiconductor layer structure (Operation 520). The spacer is at least partially removed the sidewalls of the first mask (Operation 530). The semiconductor layer structure is then etched to form a gate trench that is self-aligned with the implanted region (Operation 540).

In the description above, each example embodiment has a certain conductivity type. It will be appreciated that opposite conductivity type devices may be formed by simply reversing the conductivity of the n-type and p-type layers in each of the above embodiments. Thus, it will be appreciated that the present invention covers both n-channel and p-channel devices for each different device structure (e.g., MOSFET, IGBT, etc.).

The present invention has primarily been discussed above with respect to silicon carbide based power semiconductor devices. It will be appreciated, however, that silicon carbide is used herein as an example and that the devices discussed herein may be formed in any appropriate wide band-gap semiconductor material system. As an example, gallium nitride based semiconductor materials (e.g., gallium nitride, aluminum gallium nitride, etc.) may be used instead of silicon carbide in any of the embodiments described above.

Embodiments of the present invention have been described above with reference to the accompanying drawings, in which embodiments of the invention are shown. It will be appreciated, however, that this invention may, however, be embodied in many different forms and should not be construed as limited to the embodiments set forth above. Rather, these embodiments are provided so that this disclosure will be thorough and complete, and will fully convey the scope of the invention to those skilled in the art. Like numbers refer to like elements throughout.

Herein, the term “plurality” means two or more. Herein, “substantially” means within +/−10%.

It will be understood that, although the terms first, second, etc. are used throughout this specification to describe various elements, these elements should not be limited by these terms. These terms are only used to distinguish one element from another. For example, a first element could be termed a second element, and, similarly, a second element could be termed a first element, without departing from the scope of the present invention. The term “and/or” includes any and all combinations of one or more of the associated listed items.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

It will be understood that when an element such as a layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “top” or “bottom” may be used herein to describe a relationship of one element, layer or region to another element, layer or region as illustrated in the figures. It will be understood that these terms are intended to encompass different orientations of the device in addition to the orientation depicted in the figures.

Embodiments of the invention are described herein with reference to cross-section illustrations that are schematic illustrations of idealized embodiments (and intermediate structures) of the invention. The thickness of layers and regions in the drawings may be exaggerated for clarity. Additionally, variations from the shapes of the illustrations as a result, for example, of manufacturing techniques and/or tolerances, are to be expected. Embodiments of the invention are also described with reference to a flow chart. It will be appreciated that the steps shown in the flow chart need not be performed in the order shown.

Some embodiments of the invention are described with reference to semiconductor layers and/or regions which are characterized as having a conductivity type such as n-type or p-type, which refers to the majority carrier concentration in the layer and/or region. Thus, n-type material has a majority equilibrium concentration of negatively charged electrons, while p-type material has a majority equilibrium concentration of positively charged holes. Some material may be designated with a “+” or “−” (as in n+, n−, p+, p−, n++, n−−, p++, p−−, or the like), to indicate a relatively larger (“+”) or smaller (“−”) concentration of majority carriers compared to another layer or region. However, such notation does not imply the existence of a particular concentration of majority or minority carriers in a layer or region.

In the drawings and specification, there have been disclosed typical embodiments of the invention and, although specific terms are employed, they are used in a generic and descriptive sense only and not for purposes of limitation, the scope of the invention being set forth in the following claims.

1-12. (canceled)

13. A method of forming a semiconductor device, the method comprising:
forming a first mask on a semiconductor layer structure, the first mask including a longitudinally-extending first opening that has a first width;
forming a spacer on sidewalls of the first mask that are exposed by the first opening to form a second mask, the first and second masks comprising a mask structure that has a longitudinally-extending second opening that has a second width that is smaller than the first width;
implanting dopants into the semiconductor layer structure through the second opening to form an implanted region in the semiconductor layer structure;
at least partially removing the spacer from the sidewalls of the first mask to form a third opening in the mask structure; and
etching the semiconductor layer structure using the mask structure as an etch mask to form a gate trench in the semiconductor layer structure underneath the third opening.

14. The method of claim 13, wherein the second mask comprises silicon.

15. The method of claim 14, wherein the second mask further comprises oxygen.

16-17. (canceled)

18. The method of claim 13, wherein the implanted region is underneath the gate trench and a width of the implanted region is larger than a width of the gate trench.

19. The method of claim 18, wherein the implanted region extends onto lower portions of opposed sidewalls of the gate trench.

20. The method of claim 13, wherein lower corners of the gate trench are rounded corners.

21-22. (canceled)

23. The method of claim 13, wherein the implanted region is self-aligned with the gate trench

24. The method of claim 13, further comprising removing some but not all of a portion of the second mask that is within the second opening prior to implanting the dopants into the semiconductor layer structure.

25. The method of claim 13, wherein etching the semiconductor layer structure using the mask structure as an etch mask to form a gate trench in the semiconductor layer structure underneath the third opening exposes the implanted region.

26-28. (canceled)

29. A method of forming a semiconductor device, the method comprising:
forming a first mask on a semiconductor layer structure, the first mask including a first opening;
forming a spacer on sidewalls of the first mask that are exposed by the first opening to form a second mask, the first and second masks comprising a mask structure that has a second opening;
implanting dopants into the semiconductor layer structure through the second opening to form an implanted region in the semiconductor layer structure;
at least partially removing the spacer from the sidewalls of the first mask; and
etching the semiconductor layer structure to form a gate trench that is self-aligned with the implanted region.

30. The method of claim 29, wherein the semiconductor layer structure is a wide band-gap semiconductor layer structure that comprises a drift region having a first conductivity type, a well layer having a second conductivity type, and a source region having the first conductivity type on the well layer, wherein the dopants that are implanted into the semiconductor layer structure through the second opening are second conductivity type dopants.

31. The method of claim 30, wherein at least partially removing the spacer from the sidewalls of the first mask comprises completely removing the spacer from the sidewalls of the first mask so that the semiconductor layer structure is etched solely using the first mask as an etch mask.

32. The method of claim 30, wherein the implanted region is a trench shielding region that has the second conductivity type.

33-34. (canceled)

35. The method of claim 29, the method further comprising, after, etching the semiconductor layer structure to form the gate trench:
removing the first mask;
oxidizing exposed portions of the semiconductor layer structure; and
removing the oxidized portions of the semiconductor layer structure.

36. (canceled)

37. The method of claim 29, wherein the second mask comprises silicon and oxygen and the first mask comprises both silicon and nitrogen.

38-40. (canceled)

41. The method of claim 29, wherein the implanted region is underneath the gate trench and a width of the implanted region is larger than a width of the gate trench.

42. The method of claim 41, wherein the implanted region extends onto lower portions of opposed sidewalls of the gate trench.

43. A method of forming a semiconductor device, the method comprising:
providing a semiconductor layer structure that comprises a drift region having a first conductivity type, a well region having a second conductivity type on the drift region, and a source region having the first conductivity type on the well region;
forming a first mask on the semiconductor layer structure, the first mask including a first opening;
implanting second conductivity type dopants into the semiconductor layer structure through at least a portion of the semiconductor layer structure that was exposed by the first opening to form an implanted region that has the second conductivity type in the drift region,
wherein after the second conductivity type dopants are implanted into the semiconductor layer structure a portion of the source region that is exposed through the first opening still has the first conductivity type.

44. The method of claim 43, wherein after the second conductivity type dopants are implanted into the semiconductor layer structure a portion of the drift region that is in between the well region and the implanted region still has the first conductivity type.

45. The method of claim 44, wherein the first opening is a longitudinally-extending first opening that has a first width, the method further comprising forming a spacer on sidewalls of the first mask that are exposed by the first opening to form a second mask, the first and second masks comprising a mask structure that has a longitudinally-extending second opening that has a second width that is smaller than the first width,
wherein implanting second conductivity type dopants into the semiconductor layer structure through at least the portion of the semiconductor layer structure that was exposed by the first opening to form an implanted region that has the second conductivity type in the drift region comprises implanting the second conductivity type dopants into the semiconductor layer structure through the second opening.

46. The method of claim 45, the method further comprising:
at least partially removing the spacer from the sidewalls of the first mask to form a third opening in the mask structure; and
etching the semiconductor layer structure using the mask structure as an etch mask to form a gate trench in the semiconductor layer structure underneath the third opening.

47. The method of claim 45, wherein the first mask comprises a material that includes both silicon and nitrogen and the second mask comprises silicon.

48-49. (canceled)

50. The method of claim 49, wherein the implanted region extends onto lower portions of opposed sidewalls of the gate trench.

51-53. (canceled)
